(19) United States
(12) Patent Application Publication
(10) Pub. No.: US 2004/0014311 A1
(43) Pub. Date: Jan. 22, 2004

(54) Method for manufacturing a semiconductor device

(76) Inventor: Hyun Ahn, Seoul (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/325,394

(22) Filed: Dec. 19, 2002

(30) Foreign Application Priority Data
Dec. 19, 2001 (KR) 2001-81380

(51) Int. Cl. H01L 21/311; H01L 21/4763

(52) U.S. Cl. 438/637; 438/701

(57) ABSTRACT

A method for manufacturing a semiconductor device includes the steps of: preparing a semiconductor substrate having a predetermined substructure; stacking an interlayer insulating layer on the semiconductor substrate; depositing a photoresist layer on the interlayer insulating layer; patterning the photoresist layer into a predetermined pattern to form a photoresist layer pattern; enlarging the photoresist layer pattern by performing an isotropic dry etching process to the photoresist layer pattern; and forming a contact hole by performing an etching process by utilizing the enlarged photoresist layer pattern as an etching mask. A contact plug is formed by uniformly isotropically dry etching side walls of the photoresist layer pattern and enlarging the etched photoresist layer pattern to a desired width, while suppressing the deformation of the photoresist layer pattern, whereby, in the process of forming and etching a contact hole, the size of the contact hole can be increased and the electrical characteristics of the semiconductor device can be improved because the resistance is reduced.

### BACKGROUND

1. Technical Field

A semiconductor device manufacturing method is disclosed and, more particularly, to a method for manufacturing a semiconductor device is disclosed which is capable of forming a contact hole for a plug by uniformly isotropically dry etching side walls of the photoresist layer pattern and enlarging the etched photoresist layer pattern to a desired width, while suppressing the deformation of the photoresist layer pattern, and using the enlarged photoresist layer pattern as a mask and during the dry etch.

2. Description of the Related Art

Generally, in semiconductor manufacturing processes, a contact hole is a means for connecting two upper and lower conductive layers with an insulating layer therebetween. As the pitch of semiconductor devices is reduced and the aspect ratio is increased with the high integration of the semiconductor device, the diameter of the contact hole becomes smaller.

FIGS. 1a and 1b are cross-sectional views for representing one of conventional methods for forming a contact hole of a semiconductor device.

As shown in FIG. 1a, after an interlayer insulating layer 110 is formed on a semiconductor substrate 100 having a predetermined substructure, a photoresist layer pattern 120 is formed to form a contact hole forming region 130 by coating a photoresist layer on the upper portion of the interlayer insulating layer 110.

Thereafter, as shown in FIG. 1b, a contact hole 140 is formed by performing an etching process of a self-aligned contact (SAC) by utilizing the photoresist layer pattern 120 as an etching mask. FIG. 2 is a photograph taken by a semiconductor electron microscope (SEM) to represent the result of FIG. 1b.

At this time, there is the problem that the resistance of the contact hole 140 is reduced since an etched surface of the interlayer insulating 110 is inclined during the SAC contact etching process.

Accordingly, to ensure a SAC yield while employing the current process, a critical dimension (CD) at a lower portion of the interlayer insulating layer 110 has to be reduced. This increases the contact resistance greatly. Here, CD is the distance between a point A and a point A′ marked on the photoresist layer pattern 120 shown in FIG. 1a. Therefore, in order to solve the above described problem, if the CD at the lower portion of the contact hole 140 is increased, it can generate a bridge between the contacts 140 as shown in FIG. 2.

### SUMMARY OF THE DISCLOSURE

A method for manufacturing a semiconductor device is disclosed which is capable of forming a contact plug by uniformly isotropically dry etching the side walls of the photoresist layer pattern and enlarging the etched photoresist layer pattern to a desired width, while suppressing the deformation of the photoresist layer pattern, whereby, in the process of forming and etching a contact hole, the size of the contact hole can be increased and the electrical characteristics of the semiconductor device can be improved because the resistance is reduced.

A disclosed method for manufacturing a semiconductor device comprises preparing a semiconductor substrate having a predetermined substructure; stacking an interlayer insulating layer on the semiconductor substrate; depositing a photoresist layer on the interlayer insulating layer; patterning the photoresist layer into a predetermined pattern to form a photoresist layer pattern; enlarging the photoresist layer pattern by performing an isotropic dry etching process to the photoresist layer pattern; and forming a contact hole by performing an etching process by utilizing the enlarged photoresist layer pattern as an etching mask.

The isotropic dry etching process is performed by using plasma and by using a mixture of argon (Ar) gas and oxygen (O₂) gas.

The isotropic dry etching process is performed by using a mixture of argon (Ar) gas and oxygen (O₂) gas.

The isotropic dry etching is performed over a time period ranging from about 6 to about 20 seconds.

The isotropic dry etching is performed at a pressure ranging from about 50 to about 100 mTorr by supplying RF input power ranging from about 200 to about 300 W.

In addition, another disclosed method for manufacturing a semiconductor device comprises preparing a semiconductor substrate having a predetermined substructure; stacking an interlayer insulating layer on the semiconductor substrate; depositing a photoresist layer on the interlayer insulating layer; patterning the photoresist layer into a predetermined pattern to form a photoresist layer pattern; enlarging the photoresist layer pattern by performing an isotropic dry etching process to the photoresist layer pattern; and forming a contact hole using the photoresist layer pattern as an etching mask simultaneously with enlarging the photoresist layer pattern by performing an isotropic dry etching process on the photoresist layer pattern.

### BRIEF DESCRIPTION OF DRAWINGS

The above features and advantages of the disclosed methods will become more apparent from the following detailed description when taken in conjunction with the accompanying drawings, wherein:

FIGS. 1a and 1b are cross-sectional views representing one of conventional methods for forming a contact hole of a semiconductor device;

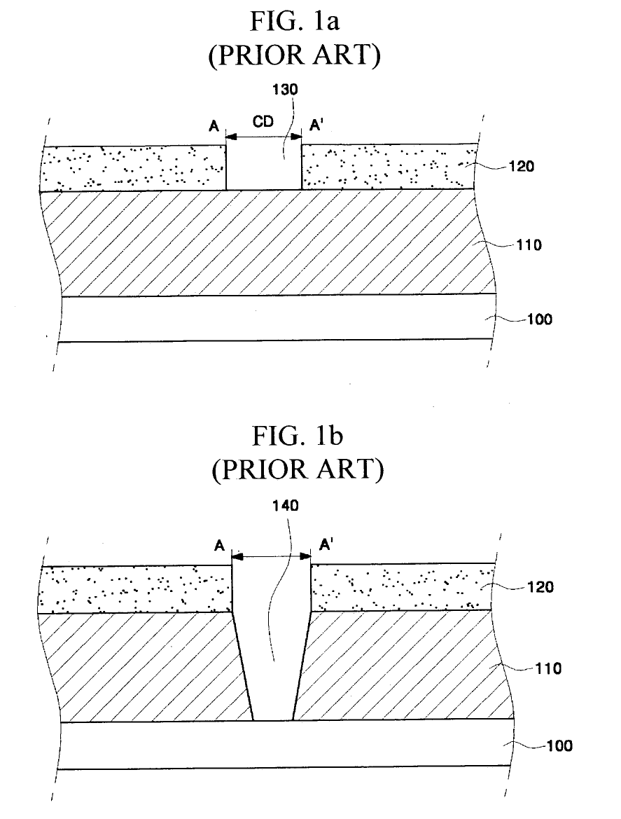

FIG. 2 is a photograph taken by a semiconductor electron microscope (SEM) to represent the result of FIG. 1b;

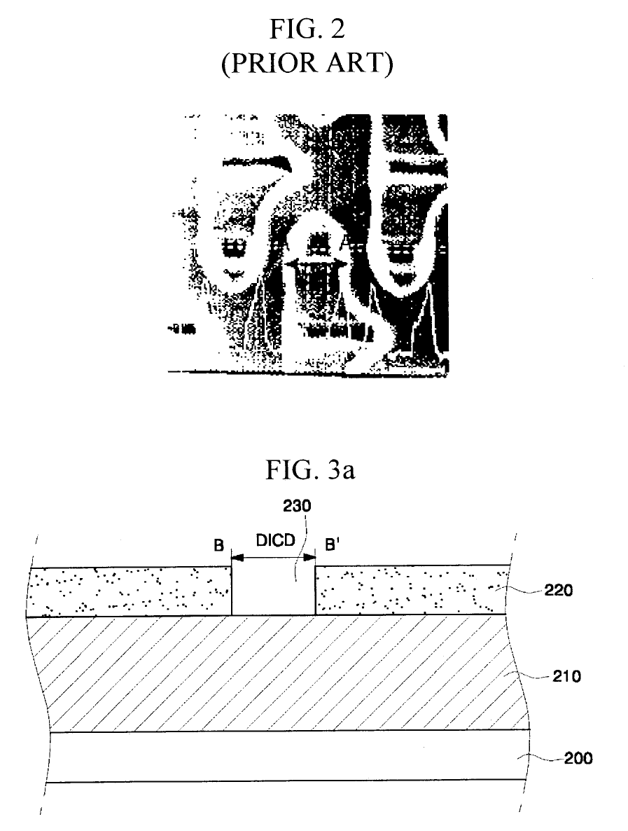

FIGS. 3a to 3c are cross-sectional views representing a first disclosed method for forming a contact hole of a semiconductor device;

FIGS. 4a to 4c are SEM photographs sequentially showing the shapes of a photoresist layer pattern which is enlarged in accordance with the first disclosed method;

FIGS. 5a to 5c are cross-sectional views representing a second disclosed method for forming a contact hole of a semiconductor device; and

FIG. 6 is an SEM photograph of the result illustrated in FIG. 5b.

### DETAILED DESCRIPTION OF THE PRESENTLY PREFERRED EMBODIMENTS

A preferred embodiment will now be described with reference to the accompanying drawings.

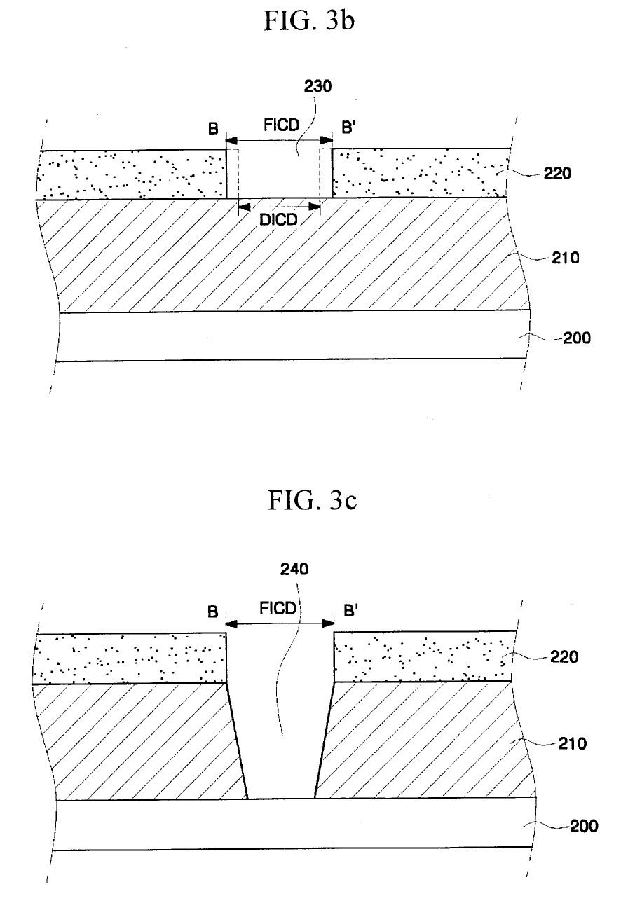

FIGS. 3a to 3c are cross-sectional views representing a first disclosed method for forming a contact hole of a semiconductor device.

As shown in FIG. 3a, a semiconductor substrate 200 having a predetermined substructure is prepared. Then, an interlayer insulating layer 210 is formed on the semiconductor substrate 200 by depositing a material such as boron phosphorous silicate glass (BPSG), phosphorous silicate glass (PSG) or the like. Thereafter, a photoresist layer pattern 220 is formed on the upper surface of the interlayer insulating layer 210 to form a contact hole forming area 230 thereon. At this time, a critical dimension (CD) of the photoresist layer pattern 220 is referred to as a direct inspection critical dimension (DICD). Preferably, the semiconductor substrate 200 is made of a material such as silicon. The photoresist material for forming the photoresist layer pattern 240 may be a positive photoresist or a negative photoresist.

As shown in FIG. 3b, during the process of forming the photoresist layer pattern 220 to form the contact hole 240, the photoresist layer pattern 220 is formed in such a manner that side walls of the photoresist layer pattern 220 are uniformly isotropically dry etched and the etched photoresist layer pattern 220 is enlarged to a desired width while suppressing the deformation of the photoresist layer pattern 220. Then, a contact hole 240 is formed by using the enlarged photoresist layer pattern 220 as a mask and etching it. As a result, the size of the contact hole 240 can be increased and accordingly, the electrical resistance of the semiconductor device can be reduced.

The DICD of the photoresist layer pattern 220 is enlarged by performing an isotropic dry etching using plasma by setting the etching time according to the desired CD of the photoresist layer pattern 220. At this time, a CD of the photoresist layer pattern 220 enlarged by the isotropic dry etching is referred to as a final inspection critical dimension (FICD).

Also, during the isotropic dry etching process, a mixture of argon (Ar) gas and a considerable amount of oxygen (O₂) gas is used for etching the photoresist layer pattern 220. At this time, the argon gas is used for plasma stabilization. Also, during the isotropic dry etching, a low RF input power ranging from about 200 to about 300 W is supplied so that reactive ions are isotropically incident and the isotropic dry etching is performed at a high pressure ranging from about 50 to about 100 mTorr so that reactive radicals move isotropically. The isotropic dry etching is performed over a time interval ranging from about 6 to about 20 seconds.

During the isotropic dry etching, a flow amount ranging from about 30 to about 50 sccm of oxygen gas and a flow amount ranging from about 100 to about 200 sccm of argon (Ar) gas are supplied.

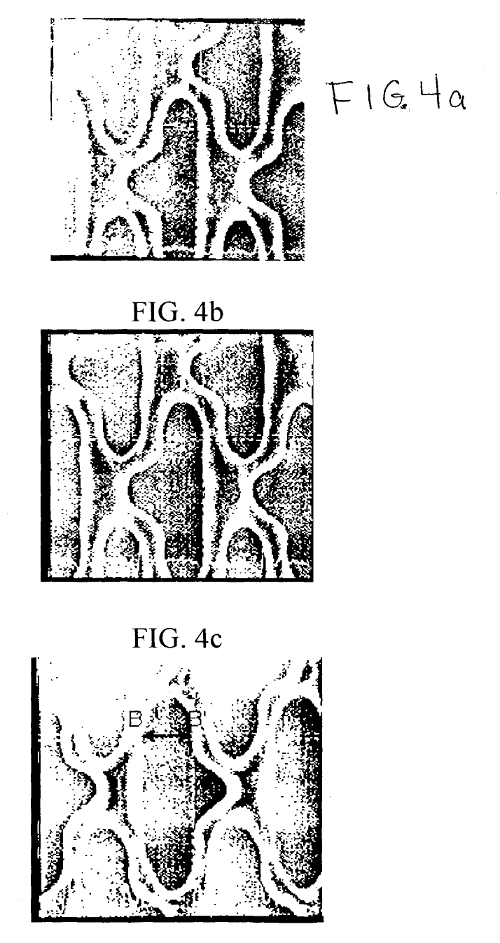

FIGS. 4a to 4c illustrate photographs taken by the SEM to sequentially show the shapes of a photoresist layer pattern 220 which is enlarged from a DICD to a FICD by performing the isotropic dry etching on the photoresist layer pattern 220 with the DICD by 6 seconds, 10 seconds and 20 seconds, respectively. This shows that the CD of the photoresist layer pattern 220 is proportional to the etching time.

As shown in FIG. 3c, the interlayer insulating layer 210 is etched by using the photoresist layer pattern 220 of the enlarged FICD as an etching mask to thereby obtain the contact hole 240.

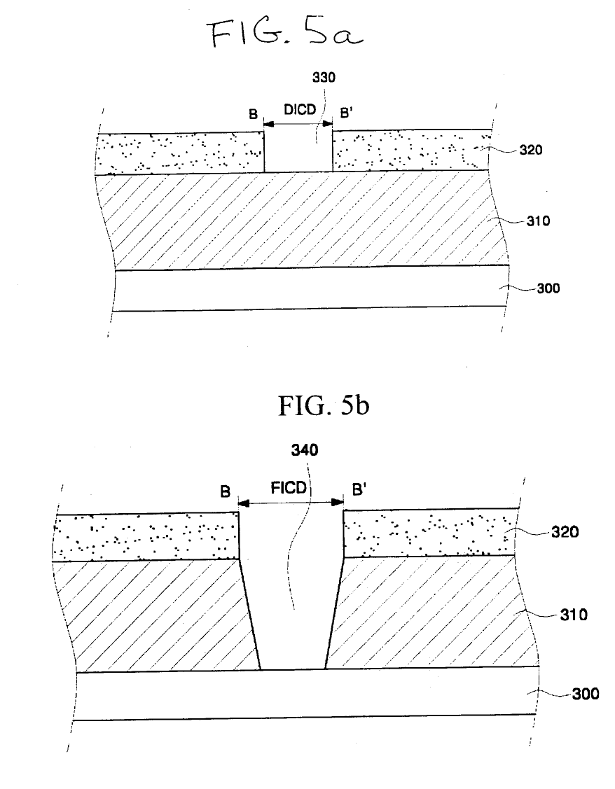

FIGS. 5a to 5c are cross-sectional views for representing a second disclosed method for forming a contact hole of a semiconductor device.

As shown in FIG. 5a, a semiconductor substrate 300 having a predetermined substructure is prepared. Then, an interlayer insulating layer 310 is formed on the semiconductor substrate 300 by depositing a material such as BPSG, PSG or the like. Thereafter, a photoresist layer pattern 318 is formed on the upper surface of the interlayer insulating layer 310 to form a contact hole forming area 330 thereon. At this time, a critical dimension (CD) of the photoresist layer pattern 320 is referred to as a direct inspection critical dimension (DICD). Preferably, the semiconductor substrate 300 is made of a material such as silicon. The photoresist material for forming the photoresist layer pattern 320 may be a positive photoresist or a negative photoresist.

As shown in FIG. 5b, the DICD of the photoresist layer pattern 320 is enlarged by performing an isotropic dry etching process using plasma by setting an etching time according to a desired CD of the photoresist layer pattern 320. Simultaneously, a contact hole 340 is formed by an etching process using the photoresist layer pattern 320 with the enlarged FICD as an etching mask

At this time, during the isotropic dry etching process, a mixture of a considerable amount of oxygen (O₂) gas and argon (Ar) gas for plasma stabilization is used for etching the photoresist layer pattern 320. During the isotropic dry etching, a low RF input power ranging from 200 to 300W is applied so that reactive ions are isotropically incident and the isotropic dry etching is performed at a high pressure ranging from about 50 to about 100 mTorr so that reactive radicals move isotropically.

During the isotropic dry etching, a flow amount ranging from about 30 to about 50 sccm of oxygen gas and a flow amount ranging from about 100 to about 200 sccm of argon gas are supplied.

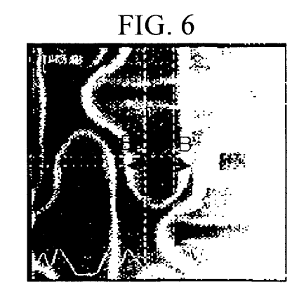

FIG. 6 is a photograph taken by the SEM representing the result of FIG. 5b in which the CD of the contact hole 340 manufactured in accordance with the second preferred embodiment of the present invention is enlarged by 20% over the conventional method.

While the disclosed methods have been described with respect to the preferred embodiments, other modifications and variations may be made without departing from the spirit and scope of this disclosure as set forth in the following claims.

Therefore, as described above, according to the disclosed methods for manufacturing semiconductor devices, the photoresist layer pattern is formed in such a manner that side walls of the photoresist layer pattern are uniformly isotropically dry etched and the etched photoresist layer pattern is enlarged to a desired width while suppressing the deformation of the photoresist layer pattern. Then, a contact hole is formed by using the enlarged photoresist layer pattern as a mask and etching it. Thus the size of the contact hole 240 can be increased and accordingly the electrical resistance of the semiconductor device can be reduced. Also, the manufacturing process is simplified and manufacturing costs is reduced since the size of the contact hole can be increased without adding additional manufacturing steps and extending the etching time.

What is claimed is:

1. A method for manufacturing a semiconductor device comprising:
stacking an interlayer insulating layer on a semiconductor substrate;
depositing a photoresist layer on the interlayer insulating layer;
patterning the photoresist layer into a predetermined pattern to form a photoresist layer pattern;
enlarging the photoresist layer pattern by performing an isotropic dry etching process on the photoresist layer pattern; and
forming a contact hole by performing an etching process by utilizing the enlarged photoresist layer pattern as an etching mask.

2. The method of claim 1, wherein the isotropic dry etching is performed using a plasma.

3. The method of claim 1, wherein the isotropic dry etching is performed by using a mixture of argon (Ar) gas and oxygen (O₂) gas.

4. The method of claim 1, wherein the isotropic dry etching is performed over a time period ranging from about 6 to about 20 seconds.

5. The method of claim 1, wherein the isotropic dry etching is performed at a pressure ranging from about 50 to about 100 mTorr by supplying RF input power ranging from about 200 to about 300 W.

6. The method of claim 3, wherein the mixture gas is combined by mixing a flow amount ranging from about 100 to about 200 sccm of argon gas with a flow amount ranging from about 30 to about 50 sccm of oxygen gas.

7. A method for manufacturing a semiconductor device comprising:
stacking an interlayer insulating layer on a semiconductor substrate;
depositing a photoresist layer on the interlayer insulating layer;
patterning the photoresist layer into a predetermined pattern to form a photoresist layer pattern;
enlarging the photoresist layer pattern by performing an isotropic dry etching process to the photoresist layer pattern; and
forming a contact hole using the photoresist layer pattern as an etching mask simultaneously with enlarging the photoresist layer pattern by performing an isotropic dry etching process on the photoresist layer pattern.

8. The method of claim 7, wherein the isotropic dry etching is performed using a plasma.

9. The method of claim 7, wherein the isotropic dry etching is performed by a mixture of argon gas and oxygen gas.
